(19) United States
(12) Patent Application Publication
(10) Pub. No.: US 2024/0195349 A1
(43) Pub. Date: Jun. 13, 2024

(54) MAXIMIZING SOLAR PANEL POWER GENERATION WITH PIEZOELECTRIC SPRINGS

(71) Applicant: INTERNATIONAL BUSINESS MACHINES CORPORATION, ARMONK, NY (US)

(72) Inventors: Sarbajit K. Rakshit, Kolkata (IN); Jagabondhu Hazra, Bangalore (IN); Manikandan Padmanaban, Chennai (IN); Marc Henri Coq, Hopewell Junction, NY (US)

(21) Appl. No.: 18/065,420

(22) Filed: Dec. 13, 2022

(51) Int. Cl. H02S 20/30; G01B 5/24; H01L 31/02; H02S 10/10; H02S 40/30; H10N 30/30

(52) U.S. Cl. CPC H02S 20/30; G01B 5/24; H01L 31/02021; H01L 41/113; H02S 10/10; H02S 40/30

(57) ABSTRACT

An approach for adjusting an inclination angle and a raindrop impact angle of a solar panel to maximize power output. The approach predicts an impact angle of a plurality of raindrops on an inclined solar panel. The approach predicts solar irradiance striking the inclined solar panel. The approach calculates an optimal solar panel inclination angle and an optimal solar panel radial angle based on maximizing power output. The approach adjusts the solar panel inclination angle and solar panel radial angle based on the optimal solar panel inclination angle and an optimal solar panel radial angle.

### BACKGROUND

The present disclosure relates generally to the field of solar panel power generation, and more particularly to maximizing power generation based on capturing kinetic energy from raindrops impacting a solar panel.

Maximizing total energy output, often results in solar panels oriented in their mounts to face south (in the Northern Hemisphere) or north (in the Southern Hemisphere) and tilted to allow for the latitude. Accordingly, the tilting of the solar panels results in a difference in elevation, with respect to the surface under the solar panel, between the two opposite ends of a solar panel.

Solar farms are capital intensive, e.g., it is estimated that a one megaWatt (MW) solar farm requires an investment of one million dollars. Consequently, solar farms generate power for eight to nine hours a day, e.g., during daylight hours, and remain idle for rest of the day. With the exponential increase in land cost, return on invest of a solar farm is not a very attractive investment anymore. Typically, solar panels are installed in outdoor open areas. These outdoor open areas are exposed to both periods of solar irradiation and periods of cloud cover and rainfall. A need has arisen to make solar farms more efficient for continued viability, e.g., there is a need to harvest additional renewable energy in combination with the utilization of solar panels.

Existing optimization solutions involving rainfall are focusing on more efficient designing of solar panel by providing multiple layers of thin/transparent coating material to capture the frictional force of water generating static electricity based on traversing a solar panel after impact. Specifically, placing two transparent polymer layers on top of a solar photovoltaic (PV) cell such that when raindrops impact the solar panel layers and then roll off, the friction generates a static electricity charge. Additional optimizations of solar panel energy generation are desired during periods of rainfall both during the day and the night.

Rain drizzle drops fall approximately at speeds from 0.7 to 2 meters per second (m/s), i.e., 2 to 7 feet per second (ft/s) for drop sizes of 0.2 to 0.5 millimeters (mm) in diameter. Rain drops fall approximately at speeds from 2 to 9 m/s, i.e., 7 to 30 ft/s for drop sizes of 0.6 to 4 mm in diameter. Larger diameter rain drops, e.g., greater than 4 to 5 mm have been observed to fall at approximately 9 m/s, i.e., 30 ft/s and even larger rain drops at up to 13 m/s, i.e., 42 ft/s, but rain drops of this size occur only in rare circumstances.

The weight of a raindrop is dependent on the size of the rain drop. Consider a raindrop having a radius of approximately 0.2 cm having a mass of approximately 0.034 grams (g). Based on the volume of rain, the amount of kinetic energy of a rainstorm can be large over a defined boundary and this kinetic energy can be captured and converted to electricity.

A spring-type piezoelectric energy harvester can be integrated into a solar panel. The energy harvester consists of a bi-layered structure composed of a surface electrode and a ferroelectric polymer, on a conventional spring. The bi-layered structure can have two roles, the core electrode and the mechanical substrate for the ferroelectric polymer.

### BRIEF SUMMARY

According to an embodiment of the present invention, a computer-implemented method for adjusting an inclination angle and a radial angle of a solar panel to maximize power output, the computer-implemented method comprising: predicting, by one or more processors, an impact angle of a plurality of raindrops on an inclined solar panel; predicting, by the one or more processors, solar irradiance striking the inclined solar panel; calculating, by the one or more processors, an optimal solar panel inclination angle and an optimal radial angle based on maximizing power output; and adjusting, by the one or more processors, the solar panel inclination angle and radial angle based on the optimal solar panel inclination angle and the optimal radial angle.

According to an embodiment of the present invention, a system for adjusting an inclination angle and a radial angle of a solar panel to maximize power output, the system comprising: a solar panel; a mounting system for the solar panel; an array of piezoelectric springs attached to a base and to a bottom face of the solar panel; one or more motors and gears for changing a solar panel inclination angle of the solar panel and a radial angle of the solar panel; one or more computer processors and memory for executing program instructions; one or more non-transitory computer readable storage media; and program instructions stored on the one or more non-transitory computer readable storage media, the program instructions comprising: program instructions to predict an impact angle of a plurality of raindrops on an inclined solar panel; program instructions to predict solar irradiance striking the inclined solar panel; program instructions to calculate an optimal solar panel inclination angle and an optimal radial angle based on maximizing power output; and program instructions to adjust the solar panel inclination angle and radial angle based on the optimal solar panel inclination angle and the optimal radial angle.

According to an embodiment of the present invention, a computer program product for adjusting an inclination angle and a radial angle of a solar panel to maximize power output, the computer program product comprising: one or more non-transitory computer readable storage media and program instructions stored on the one or more non-transitory computer readable storage media, the program instructions comprising: program instructions to predict an impact angle of a plurality of raindrops on an inclined solar panel; program instructions to predict solar irradiance striking the inclined solar panel; program instructions to calculate an optimal solar panel inclination angle and an optimal radial angle based on maximizing power output; and program instructions to adjust the solar panel inclination angle and radial angle based on the optimal solar panel inclination angle and the optimal radial angle.

Other aspects and embodiments of the present invention will become apparent from the following detailed description, which, when taken in conjunction with the drawings, illustrate by way of example the principles of the invention.

### BRIEF DESCRIPTION OF THE DRAWINGS

FIG. 1 depicts a cloud computing environment and a high-level architecture, in accordance with at least one embodiment of the present invention.

FIG. 2 depicts raindrops impacting a solar panel mounted to an array of piezoelectric springs and a base, in accordance with at least one embodiment of the present invention.

FIG. 3A depicts a solar panel in a mount with an array of piezoelectric springs and a base adjusted to an optimal inclination and radial angle, in accordance with at least one embodiment of the present invention.

FIG. 3B depicts a solar panel with a water runoff collection channel and an array of piezoelectric springs beneath the water runoff collection channel, in accordance with at least one embodiment of the present invention.

FIG. 4 depicts an exemplary detailed architecture, in accordance with at least one embodiment of the present invention.

FIG. 5 depicts a flowchart of a method for adjusting the inclination angle and the radial angle of a solar panel to maximize power output, in accordance with at least one embodiment of the present invention.

### DETAILED DESCRIPTION

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 100 contains an example of an environment for the execution of at least some of the computer code involved in performing the inventive methods, such as Solar Panel Adjustment Component 150. In addition to block 150, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

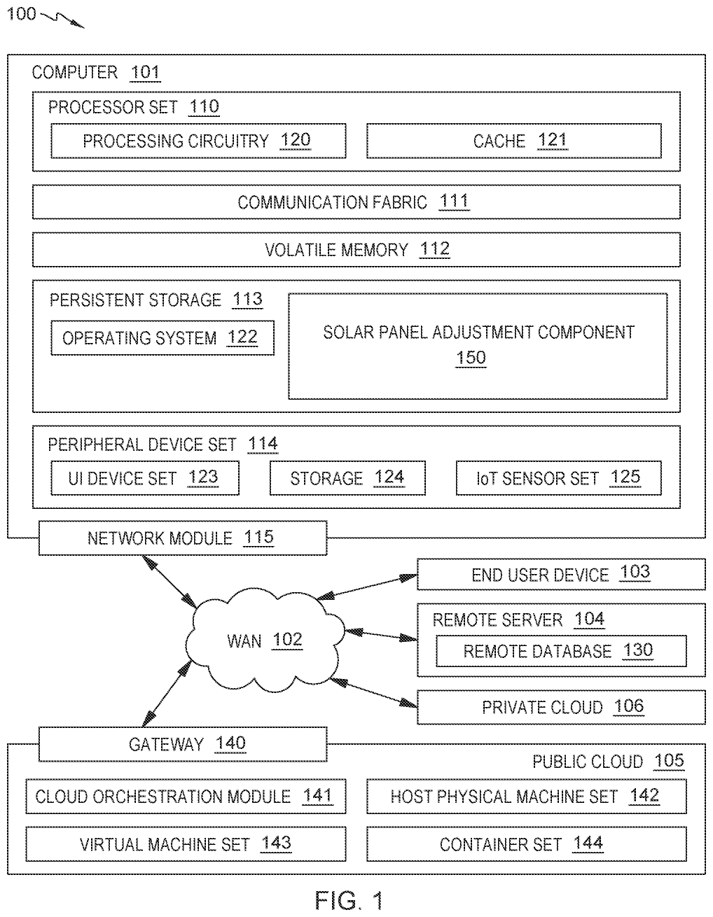

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 150 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 150 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Embodiments described herein provide the capability to combine solar panels and arrays of piezoelectric springs to maximize the energy utilization by placing the arrays of piezoelectric springs under the solar panels to recover the kinetic energy created by the impact of raindrops on the solar panels.

Further, a method is disclosed to determine, i.e., calculate, an optimal inclination angle of a mounted solar panel/piezoelectric spring array for the predicted wind direction and rainfall angle, based on localized weather data, wind speed magnitude and direction, and solar angle mount controller constraints. It should be noted that a weather forecast can be employed to assist in predicting rainfall amount and rainfall angle with respect to the solar panel mount location. It should further be noted that the calculation can be performed on a predetermined time interval.

Embodiments of the present invention disclosed herein, can capture the kinetic energy of rain drops wherein the characteristics of the freefalling raindrops are changing dynamically with changes in wind speed and direction. Accordingly, embodiments of the present invention describe a system and method that can capture the maximum kinetic energy of rain drops by considering dynamics of the rain angle and adjusting the orientation of the solar panels to maximize the captured kinetic energy.

Embodiments of the present invention disclosed herein, can capture further kinetic energy of water drops wherein the raindrops impacting a solar panel are gravity drained to a collection water channel attached to the edges of the solar panel. The collected water is directed to drip holes located above a piezoelectric spring harvester sized for the dimensions of the water channel.

It should be noted that references throughout this specification to features, advantages, or similar language herein do not imply that all the features and advantages that may be realized with the embodiments disclosed herein should be, or are in, any single embodiment of the invention. Rather, language referring to the features and advantages is understood to mean that a specific feature, advantage, or characteristic described in connection with an embodiment is included in at least one embodiment of the present invention. Thus, discussion of the features, advantages, and similar language, throughout this specification may, but do not necessarily, refer to the same embodiment.

Furthermore, the described features, advantages, and characteristics of the invention may be combined in any suitable manner in one or more embodiments. One skilled in the relevant art will recognize that the invention may be practiced without one or more of the specific features or advantages of a particular embodiment. In other instances, additional features and advantages may be recognized in certain embodiments that may not be present in all embodiments of the invention.

These features and advantages will become more fully apparent from the following drawings, description, and appended claims, or may be learned by the practice of the invention as set forth hereinafter.

The scope of the present invention is to be determined by the claims. Accordingly, any features, characteristics, advantages, or the like, discussed below in the discussion of embodiments of this specification shall not be taken to mean that such features, characteristics, advantages, or the like are required to practice the present invention as defined by the claims.

Embodiments of the present invention are described with reference to the Figures. It should be noted that although the example embodiments are illustrated as a computer component associated with a computer center, embodiments of the present invention are applicable to any system requiring removable components retained by a manually operated spring-loaded latch.

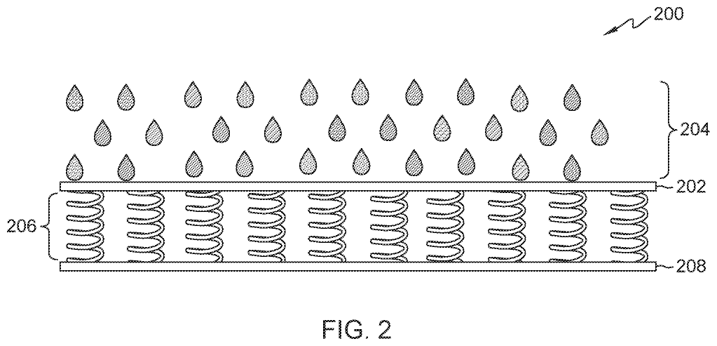

Looking to FIG. 2 is a diagram 200 depicting an embodiment of a solar panel 202 mounted on an array of piezoelectric springs 206. In another aspect of an embodiment of the present invention, the array of piezoelectric springs can be mounted on a base 208 to constrain the array of piezoelectric springs 206 between the base 208 and the solar panel 202. In another aspect of an embodiment of the present invention, rainfall 204 can impact the solar panel 202, imparting kinetic energy to solar panel 202 that is transferred to the array of piezoelectric springs 206, and captured as electrical energy based on the oscillations of the array of piezoelectric springs 206.

During rainfall, raindrops can impact the solar panel 202, resulting in the transfer of the kinetic energy of the rainfall being applied across the entire surface of the solar panel 202. It should be noted that there can be a minor time delay between rain drop impacts of the rainfall 204, resulting in compression and expansion of the array of piezoelectric springs 206. In another aspect of an embodiment of the present invention, the expansion and compression of array of piezoelectric springs 206 can generate power in each piezoelectric spring 206, wherein the generated power from each piezoelectric spring 206 can be aggregated for the duration of the rainstorm. It should be noted that the kinetic energy of rainfall 204 rain drops impacting on the solar panel 202 changes dynamically based on wind speed and direction. Accordingly, embodiments of the present invention can change the solar energy system inclination dynamically, based on the rain angle, to maximize the energy harvesting.

It should be noted that a solar energy system comprising a solar panel 202, an array of piezoelectric springs 206, and a base 208 can be installed on objects such as, but not limited to, a roof on a commercial building, a roof on a home, the ground, etc. In another aspect of an embodiment of the present invention, the latitude and longitude of the solar energy system can be employed to prepare a precipitation forecast. The precipitation forecast can be combined with localized weather station based predicted wind velocity and wind direction to estimate an expected rain angle of the rainfall with an axis perpendicular to the plane of the solar energy system mounting structure.

In another aspect of an embodiment of the present invention, solar irradiance, the angle of the sun with respect to the mounting plane of the solar energy system, and the solar energy system layout can be analyzed in combination with the estimated rain angle to jointly optimize the balance between the solar energy from the solar irradiance and the kinetic energy from the rainfall raindrop impacts.

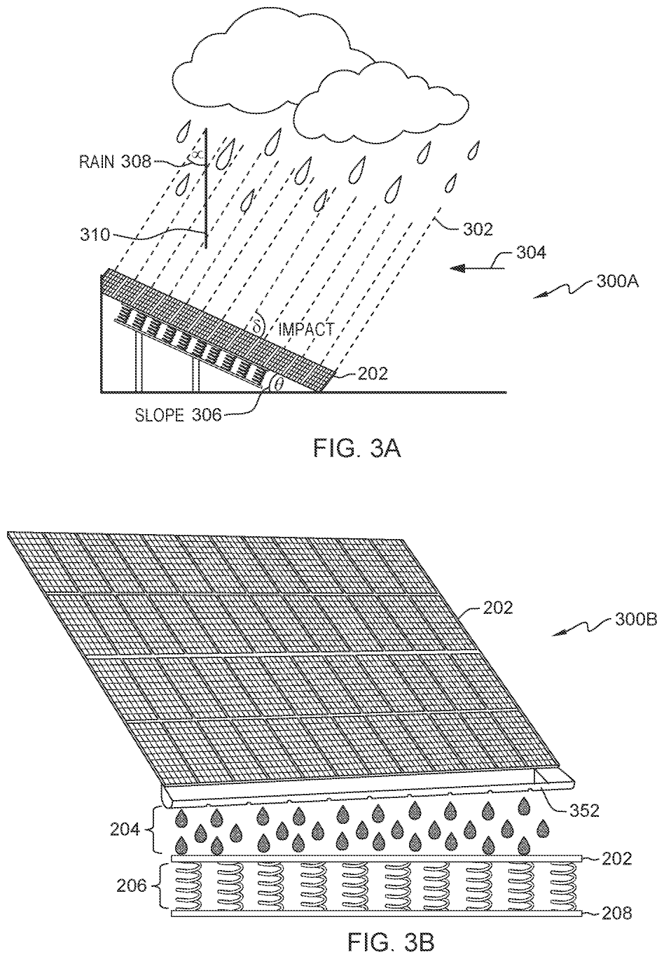

Turning now to FIG. 3A of diagram 300A, another aspect of an embodiment of the present invention can consider how raindrop fall trajectories 302 can be influenced by horizontal wind velocity 304 and geometry of a surface, slope gradient 306 and aspect, leading to differences in the amounts of raindrops hitting the solar panel 202 surface. This can be represented by the equation:

$$ϕ = \frac{{I}_{α}}{I} = cos ( α ∓ θ )$$

where I can be rainfall intensity with respect to a plane normal to the rain vector; I_{α} is actual rainfall intensity; α 308 is raindrop inclination from vertical 310; and θ 306 is slope of the gradient. Further, a mean angle of rain incidence between a wind vector and the plane of the solar panel 202 surface can be calculated as a function of the rain inclination, slope gradient and slope aspect, and given by the cosine law of spherical trigonometry based on the equation:

cos(α∓θ)=cos α cos θ∓sin α sin θ cos(z_{α}∓z_{θ})

where z_{α} and z_{θ} are an azimuth from which rain is falling and an azimuth towards which a plane of surface is inclined, respectively. It should be noted that a solar panel 202 surface experiences a maximum raindrop impact pressure when a raindrop falls perpendicular to the solar panel 202 surface.

In another aspect of an embodiment of the present invention, control of solar panel inclination can be precise and can be subject to small step changes in inclination while considering the entire prediction horizon. For example, at different inclination angles, the next angle should be chosen such that it is optimal for a predetermined number of inclination angles, based on the frequency of change in wind direction.

Looking again to an embodiment of a solar panel 202 mounted on an incline wherein the incline is appropriate for the latitude of the location where the solar panel 202 is installed is presented. In one aspect of an embodiment of the present invention, an algorithm is described that can predict a horizon optimization for the solar panels 202. In another aspect of an embodiment of the present invention, the algorithm can predict the wind velocity 304 and direction at the solar panel 202 based on factors including, but not limited to, the latitude and longitude of the solar panel 202 installation and the layout of the solar panel 202 mounting system. It should be noted that the layout can include factors such as, but not limited to, the orientation of the mounting system with respect to the wind direction, obstructions positioned at or near the mounting system, etc.

Turning now to FIG. 3B of diagram 300B, another aspect of an embodiment of the present invention can collect water draining down the face of an inclined solar panel into a water channel 352. The water channel 352 has a plurality of drain holes in the bottom allowing the collected water to escape the water channel 352 and impact a secondary array of piezoelectric springs placed directly beneath the drain holes. It should be noted that the secondary array of piezoelectric springs are dimensionally designed based on the dimensional characteristics of the water channel 352.

In another aspect of an embodiment of the present invention, the water channel can direct the water to an impoundment for subsequent release to a local or remote array of piezoelectric springs. It should be noted that a solar panel mounting system elevation can dynamically be adjusted to provide a greater fall height, i.e., greater amount of kinetic energy during periods of rainstorms.

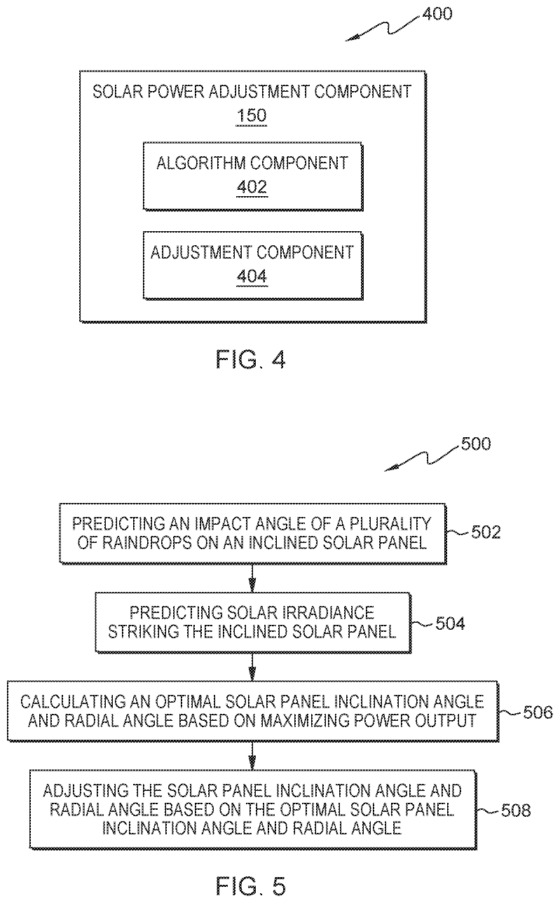

FIG. 4 is an exemplary detailed architecture for performing various operations of FIG. 3A and FIG. 3B, in accordance with various embodiments. The architecture 400 may be implemented in accordance with the present invention in any of the environments depicted in FIGS. 1-3 and 5, among others, in various embodiments. Of course, more or less elements than those specifically described in FIG. 4 may be included in architecture 400, as would be understood by one of skill in the art upon reading the present descriptions.

Architecture 400 provides a detailed view of at least some of the modules of architecture 300. Architecture 400 can comprise a solar panel adjustment component 150, which can further comprise algorithm component 402 and adjustment component 404.

Looking now to FIG. 4 and another aspect of an embodiment of the present invention, algorithm component 402 can include, but is not limited to an algorithm that can calculate a cost function over the receding horizon based on controlling solar panel inclination subject to small step changes considering the entire prediction horizon combining the solar radiance and the impact angle at the solar panel 202 to perform a joint optimization, e.g., solar and impact, to update both the slope of and the radial angle orientation of the solar panels 202. For example, at each small adjacent step, an angle can be chosen such that it is the optimal angle for the next “N” adjacent steps, based on changes in solar irradiance and raindrop impact angle as illustrated in the algorithm:

J=Σᵢ₌₁^{N}w_{H}_{ᵢ}(Hᵢ^{r}−Hᵢ^{m})²+Σᵢ₌₁^{N}w_{L}_{ᵢ}(Lᵢ^{r}−L)²+Σᵢ₌₁^{N}w_{uH}_{ᵢ}(Δu)²+Σᵢ₌₁^{N}w_{vL}_{ᵢ}(Δv)²

wherein J is a cost function over the receding horizon; Hᵢ^{r} is an optimal impact angle for an instant ‘i’ from a knowledge base; Hᵢ^{m} is a chosen impact angle for the instant ‘i;’ Lᵢ^{r} is an available irradiance for the instant ‘i’ from the knowledge base; Lᵢ^{m} is a captured irradiance for the instant ‘i;’ u, v is the impact angle and irradiance controller variable, respectively; w_{H}_{ᵢ}, w_{L}_{ᵢ} are the weighting coefficients for impact angle and irradiance, respectively; w_{uH}_{ᵢ}, w_{uL}_{ᵢ} are the penalizing coefficients for big changes in impact angle and irradiance in the controller, respectively; and H^{max}, L^{max} are the maximum limits for impact angle and irradiance level, respectively. It should be noted that the receding horizon cost function is subject to the constraints 0≤Hᵢ^{m}≤H^{max} and 0≤Lᵢ^{m}≤L^{max} for selected impact angle and captured irradiance.

In another aspect of an embodiment of the present invention, adjustment component 404 can be incorporated into a control system suitable for controlling the incline angle and radial angle orientation of a solar panel 202. The adjustment component 404 can direct outputs associated with the control system to adjust the solar panels 202 inclination and radial orientation pitch angles, based on the output from the algorithm, to optimize the power production of the solar panels 202 as localized weather changes result in changing levels of solar irradiance and rainfall.

FIG. 5 is an exemplary flowchart of a method 500 for adjusting an inclination angle and a radial angle of a solar panel to maximize power output. At step 502, an embodiment can predict an impact angle of a plurality of raindrops on an inclined solar panel. At step 504, the embodiment can predict solar irradiance striking the inclined solar panel. At step 506, the embodiment can calculate an optimal solar panel inclination angle and an optimal solar panel radial angle based on maximizing power output. At step 508, the embodiment can adjust the solar panel inclination angle and solar panel radial angle based on the optimal solar panel inclination angle and the optimal radial angle.

What is claimed is:

1. A computer-implemented method for adjusting an inclination angle and a radial angle of a solar panel to maximize power output, the computer-implemented method comprising:
predicting, by one or more processors, an impact angle of a plurality of raindrops on an inclined solar panel;
predicting, by the one or more processors, solar irradiance striking the inclined solar panel;
calculating, by the one or more processors, an optimal solar panel inclination angle and an optimal radial angle based on maximizing power output; and
adjusting, by the one or more processors, the solar panel inclination angle and radial angle based on the optimal solar panel inclination angle and the optimal radial angle.

2. The computer-implemented method of claim 1, wherein the calculating is based on an equation:
J=Σᵢ₌₁^{N}w_{H}_{ᵢ}(Hᵢ^{r}−Hᵢ^{m})²+Σᵢ₌₁^{N}w_{L}_{ᵢ}(Lᵢ^{r}−L)²+Σᵢ₌₁^{N}w_{uH}_{ᵢ}(Δu)²+Σᵢ₌₁^{N}w_{vL}_{ᵢ}(Δv)²,
wherein J is a cost function over a receding horizon; Hᵢ^{r} is an optimal impact for an instant ‘i’ from a knowledge base; Hᵢ^{m} is a chosen impact angle for the instant ‘i;’ Lᵢ^{r} is an available irradiance for the instant ‘i’ from the knowledge base; Lᵢ^{m} is a captured irradiance for the instant ‘i;’ u, v is an impact angle and irradiance controller variable, respectively; w_{H}_{ᵢ}, w_{L}_{ᵢ} are weighting coefficients for impact angle and irradiance, respectively; w_{uH}_{ᵢ}, w_{uL}_{ᵢ} are penalizing coefficients for big changes in impact angle and irradiance in a controller, respectively; H^{max}, L^{max} are maximum limits for impact angle and irradiance level, respectively; and the receding horizon cost function is subject to constraints 0≤Hᵢ^{m}≤H^{max} and 0≤Lᵢ^{m}≤L^{max} for a selected impact angle and an irradiance.

3. The computer-implemented method of claim 1, wherein the calculating is performed on a predetermined time interval.

4. The computer-implemented method of claim 1, wherein the adjusting the solar panel inclination angle and radial angle is constrained to a predetermined maximum change in inclination angle and a predetermined maximum change in radial angle.

5. The computer-implemented method of claim 4, wherein the adjusting the solar panel inclination angle and radial angle is based on an optimal angle for a predetermined number of adjacent maximum changes in angle.

6. The computer-implemented method of claim 1, wherein the predicting wind velocity is based on a latitude and longitude associated with a location of the inclined solar panel and a measured wind velocity and direction.

7. The computer-implemented method of claim 1, wherein the adjusting is performed dynamically.

8. The computer-implemented method of claim 1, further comprising:
collecting water draining from the inclined solar panel into a water channel and directing the water through drain holes in the water channel to a secondary array of piezoelectric springs position below the drain holes.

9. The computer-implemented method of claim 1, wherein predicting solar irradiance is based on a weather forecast for a latitude and longitude associated with a location of the inclined solar panel and a predicted wind velocity.

10. A system for adjusting an inclination angle and a radial angle of a solar panel to maximize power output, the system comprising:
a solar panel;
a mounting system for the solar panel;
an array of piezoelectric springs attached to a base and to a bottom face of the solar panel;
one or more motors and gears for changing a solar panel inclination angle of the solar panel and a radial angle of the solar panel;
one or more computer processors and memory for executing program instructions;
one or more non-transitory computer readable storage media; and
program instructions stored on the one or more non-transitory computer readable storage media, the program instructions comprising:
program instructions to predict an impact angle of a plurality of raindrops on an inclined solar panel;
program instructions to predict solar irradiance striking the inclined solar panel;
program instructions to calculate an optimal solar panel inclination angle and an optimal radial angle based on maximizing power output; and
program instructions to adjust the solar panel inclination angle and radial angle based on the optimal solar panel inclination angle and the optimal radial angle.

11. The system of claim 10, wherein the program instructions to calculate are based on an equation:
J=Σᵢ₌₁^{N}w_{H}_{ᵢ}(Hᵢ^{r}−Hᵢ^{m})²+Σᵢ₌₁^{N}w_{L}_{ᵢ}(Lᵢ^{r}−L)²+Σᵢ₌₁^{N}w_{uH}_{ᵢ}(Δu)²+Σᵢ₌₁^{N}w_{vL}_{ᵢ}(Δv)²,
wherein J is a cost function over a receding horizon; Hᵢ^{r} is an optimal impact for an instant ‘i’ from a knowledge base; Hᵢ^{m} is a chosen impact angle for the instant ‘i;’ Lᵢ^{r} is an available irradiance for the instant ‘i’ from the knowledge base; Lᵢ^{m} is a captured irradiance for the instant ‘i;’ u, v is an impact angle and irradiance controller variable, respectively; w_{H}_{ᵢ}, w_{L}_{ᵢ} are weighting coefficients for impact angle and irradiance, respectively; w_{uH}_{ᵢ}, w_{uL}_{ᵢ} are penalizing coefficients for big changes in impact angle and irradiance in a controller, respectively; H^{max}, L^{max} are maximum limits for impact angle and irradiance level, respectively; and the receding horizon cost function is subject to constraints 0≤Hᵢ^{m}≤H^{max} and 0≤Lᵢ^{m}≤L^{max} for a selected impact angle and an irradiance.

12. The system of claim 10, wherein the program instructions to calculate are performed on a predetermined time interval.

13. The system of claim 10, wherein the adjusting the solar panel inclination angle and radial angle is constrained to a predetermined maximum change in inclination angle and a predetermined maximum change in radial angle.

14. The system of claim 13, wherein the adjusting the solar panel inclination angle and radial angle is based on an optimal angle for a predetermined number of adjacent maximum changes in angle.

15. The system of claim 10, wherein the program instructions to predict wind velocity are based on a latitude and longitude associated with a location of the inclined solar panel and a measured wind velocity and direction.

16. The system of claim 10, wherein the program instructions to adjust are performed dynamically.

17. The system of claim 10, further comprising:
collecting water draining from the inclined solar panel into a water channel and directing the water through drain holes in the water channel to a secondary array of piezoelectric springs position below the drain holes.

18. The system of claim 10, wherein the program instructions to predict the solar irradiance are based on a weather forecast from a latitude and longitude associated with a location of the inclined solar panel and a predicted wind velocity.

19. A computer program product for adjusting an inclination angle and a radial angle of a solar panel to maximize power output, the computer program product comprising:
one or more non-transitory computer readable storage media and program instructions stored on the one or more non-transitory computer readable storage media, the program instructions comprising:
program instructions to predict an impact angle of a plurality of raindrops on an inclined solar panel;
program instructions to predict solar irradiance striking the inclined solar panel;
program instructions to calculate an optimal solar panel inclination angle and an optimal radial angle based on maximizing power output; and
program instructions to adjust the solar panel inclination angle and radial angle based on the optimal solar panel inclination angle and the optimal radial angle.

20. The computer program product of claim 19, wherein the program instructions to calculate are based on an equation:
J=Σᵢ₌₁^{N}w_{H}_{ᵢ}(Hᵢ^{r}−Hᵢ^{m})²+Σᵢ₌₁^{N}w_{L}_{ᵢ}(Lᵢ^{r}−L)²+Σᵢ₌₁^{N}w_{uH}_{ᵢ}(Δu)²+Σᵢ₌₁^{N}w_{vL}_{ᵢ}(Δv)²,
wherein J is a cost function over a receding horizon; Hᵢ^{r} is an optimal impact for an instant ‘i’ from a knowledge base; Hᵢ^{m} is a chosen impact angle for the instant ‘i;’ Lᵢ^{r} is an available irradiance for the instant ‘i’ from the knowledge base; Lᵢ^{m} is a captured irradiance for the instant ‘i;’ u, v is an impact angle and irradiance controller variable, respectively; w_{H}_{ᵢ}, w_{L}_{ᵢ} are weighting coefficients for impact angle and irradiance, respectively; w_{uH}_{ᵢ}, w_{uL}_{ᵢ} are penalizing coefficients for big changes in impact angle and irradiance in a controller, respectively; H^{max}, L^{max} are maximum limits for impact angle and irradiance level, respectively; and the receding horizon cost function is subject to constraints 0≤Hᵢ^{m}≤H^{max} and 0≤Lᵢ^{m}≤L^{max} for a selected impact angle and an irradiance.
